(19) United States
(12) Patent Application Publication
(10) Pub. No.: US 2024/0154053 A1
(43) Pub. Date: May 9, 2024

(54) GE ON SI PHOTODETECTOR WITH GAIN

(71) Applicant: Cisco Technology, Inc., San Jose, CA (US)

(72) Inventor: Gianlorenzo MASINI, Carlsbad, CA (US)

(21) Appl. No.: 18/052,884

(22) Filed: Nov. 4, 2022

(51) Int. Cl. H01L 31/109; H01L 31/028; H01L 31/18

(52) U.S. Cl. CPC H01L 31/109; H01L 31/028; H01L 31/1812

(57) ABSTRACT

Embodiments herein describe a germanium photodetector that can provide gain at low voltages. In one embodiment, the photodetector includes a P-type anode and a P-type cathode. In one embodiment, a germanium absorption region and a lighter-doped P-type region are disposed between the anode and cathode.

### TECHNICAL FIELD

Embodiments presented in this disclosure generally relate to photodetectors with gain.

### BACKGROUND

Control system are an integral part of modern optical transceivers. To stabilize Mach-Zehnder interferometers (MZI) or laser sources, a portion of the light is tapped and absorbed by a monitor photodiode. This tapping represents a loss for the optical link budget and should be minimized. The amount of light to be tapped is set by the signal to noise ratio requirements of the control system. One key component in this determination is the responsivity of the monitor photodiode. If gain is available at the monitor photodiode, a significant reduction of the tapped optical intensity can be implemented thus benefitting the link budget. Typically, avalanche photodiodes (APDs) are used to provide gains, but APDs require high voltages.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate typical embodiments and are therefore not to be considered limiting; other equally effective embodiments are contemplated.

FIG. 1 illustrates a photodetector, according to one embodiment.

FIG. 2 illustrates a photodetector, according to one embodiment.

FIG. 3 is a flowchart for forming a photodetector, according to one embodiment.

FIGS. 4A-4E illustrate steps for forming a photodetector, according to one embodiment.

FIG. 5 is a chart for a photodetector that can generate gain at low voltages and low speeds, according to one embodiment.

FIG. 6 illustrates conduction and valence bands for a germanium silicon interface, according to one embodiment.

To facilitate understanding, identical reference numerals have been used, where possible, to designate identical elements that are common to the figures. It is contemplated that elements disclosed in one embodiment may be beneficially used in other embodiments without specific recitation.

### DESCRIPTION OF EXAMPLE EMBODIMENTS

### Overview

One embodiment presented in this disclosure is a photodetector that includes a germanium absorption region and a silicon layer comprising a P-type anode region and a P-type cathode region, wherein the germanium absorption region is disposed between the anode and cathode regions.

Another embodiment is a method that includes doping a wafer to form heavily doped P-type anode and cathode regions in a silicon layer and forming a germanium absorption region between the anode and cathode regions.

Another embodiment is a photodetector that includes a germanium absorption region, a silicon layer, a P-type anode region, a P-type cathode region, wherein one of the anode region and cathode region is formed in the silicon layer and the other region is at a top of the germanium absorption region.

### Example Embodiments

Embodiments herein describe a germanium photodetector that can provide gain at lower voltages (e.g., 1-6 volts) than APDs. In one embodiment, the photodetector includes a P-type anode and a P-type cathode. That is, in most photodiodes (and in APDs), the cathode is N-type while the anode is P-type. In contrast, in the embodiments herein, both the anode and cathode are heavily doped P-type. In one embodiment, a germanium absorption region and a lighter-doped P-type region are disposed between the anode and cathode.

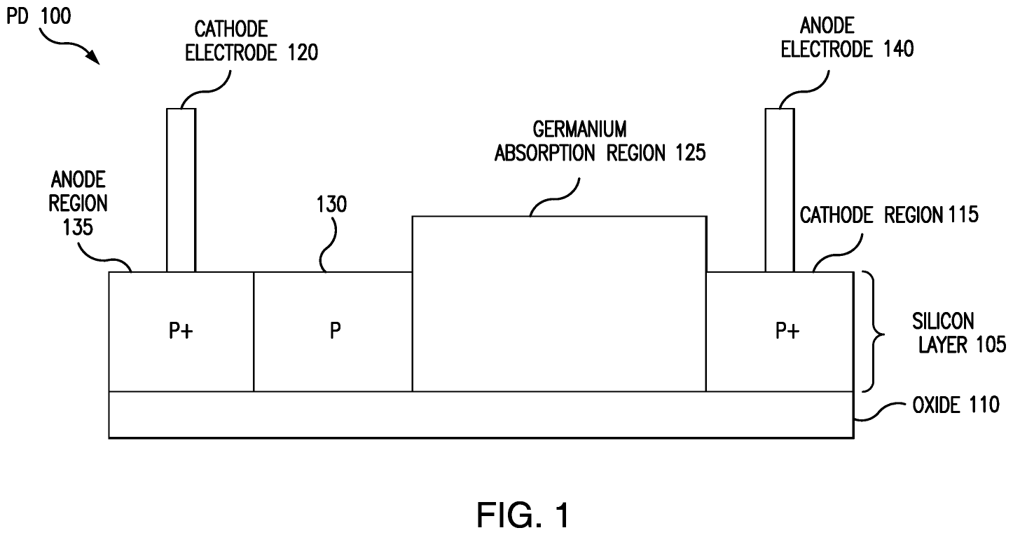

FIG. 1 illustrates a photodetector (PD) 100, according to one embodiment. The PD 100 includes a silicon layer 105 arranged on an oxide 110 (e.g., an oxide layer), which can be silicon dioxide or any other suitable insulator. In one embodiment, the oxide 110 and the silicon layer 105 are part of a SOI structure, where the oxide 110 is a buried oxide (BOX). However, the embodiments are not limited to such, and can be applied to any device that includes a crystalline silicon layer deposited on an oxide.

The silicon layer 105 includes a cathode region 115 to which a cathode electrode 120 is coupled. As shown, the cathode region 115 is doped P-type (e.g., a heavy P+ doping concentration of a P-type dopant).

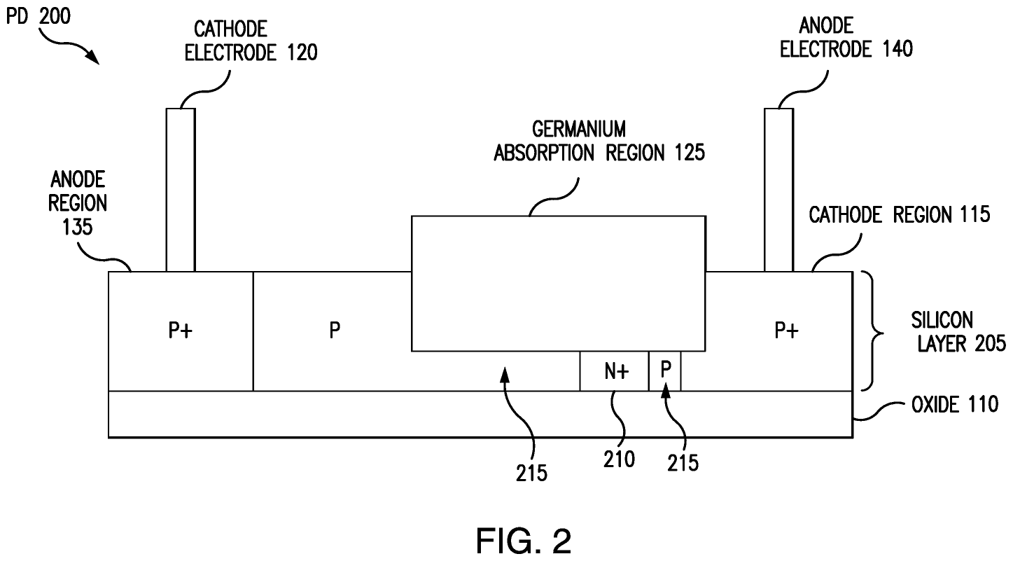

A portion of the silicon layer 105 has been removed and replaced with a germanium absorption region 125. For example, the germanium absorption region 125 can be grown or deposited in the PD 100. In FIG. 1, the germanium absorption region 125 directly contacts the oxide 110. However, as discussed later, FIG. 2 illustrates another embodiment where the germanium absorption region 125 is disposed on a portion of the silicon layer 105.

To the left of the germanium absorption region 125 is a P-type region 130 that is lighter doped P-type than the cathode region 115. That is, the P-type region 130 has a smaller concentration of a P-type dopant than the cathode region 115.

To the left of the P-type region 130 is an anode region 135 which is also heavily doped P-type (e.g., is P+). In this example, the anode region 135, the P-type region 130, and the cathode region 115 are formed from silicon in the silicon layer 105. Further, an anode electrode 140 contacts the anode region 135.

While FIG. 1 illustrates one anode and one cathode, in other embodiments, the PD 100 may have multiple anode regions or multiple cathode regions. Further, while FIG. 1 illustrates that the germanium absorption region 125 is undoped, in another embodiment the top of this region 125 can be doped P+ so it can function as the cathode region 115. In that case, the cathode electrode 120 can contact the top of the germanium absorption region 125 and the cathode region 115 to the right of the germanium absorption region 125 can be omitted. Thus, whether the cathode region is formed in the silicon (e.g., the cathode region 115) or is disposed on top of the germanium absorption region 125, both the anode and the cathode regions are P-type.

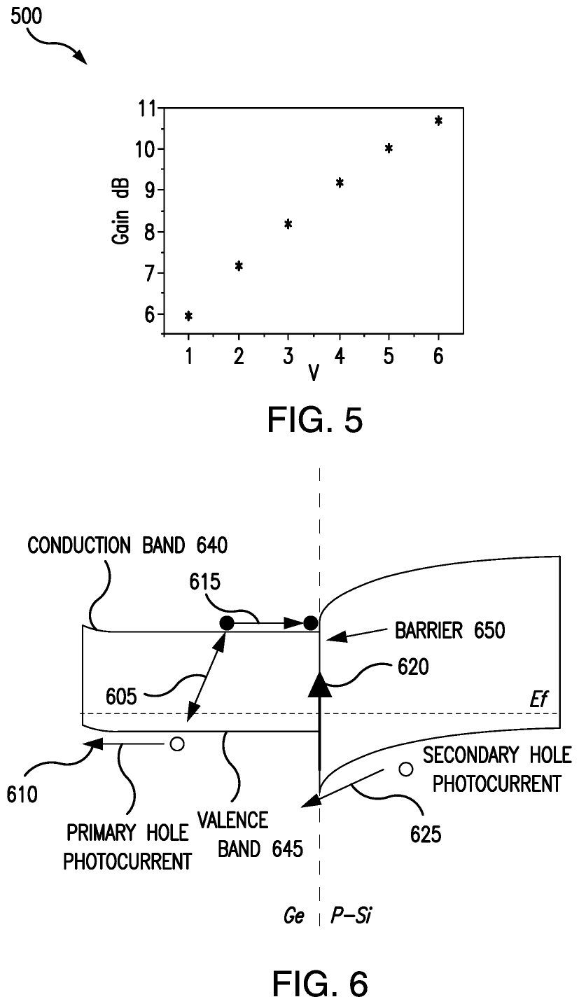

The interface between the germanium in the germanium absorption region 125 and the cathode region 115 provide a gain region of the PD 100. In general, the negative photo carriers generated in the germanium absorption region 125 can accumulate at the interface between the germanium and the cathode region 115, which changes the valence band barrier height, creating a secondary photocurrent of injected holes which can be substantially larger than the primary photocurrent, thereby resulting in gain. This is discussed more in FIG. 6 below.

Further, this gain can occur with a low bias voltage being applied between the anode electrode 140 and the cathode electrode 120 (e.g., 1 to 6 V bias voltage between the electrodes 120 and 140). While the PD 100 provides gain at low voltages, the tradeoff is that the PD 100 may have a relatively slow speed compared to typical APDs. For example, the PD 100 may have speeds sufficient for applications that rely on electrical signals in the low MHz (e.g., less than 10 MHz) and in the kHz range. One such application is control systems for modern optical transceivers where the PD 100 can be used as monitor PD. However, the PD 100 can be used in any low speed application where electrical gain is desired.

FIG. 2 illustrates a PD 200, according to one embodiment. The PD 200 includes many of the same structures as shown in the PD 100, as indicated by the same reference numbers. However, unlike in FIG. 1, in FIG. 2 a portion of a silicon layer 205 is disposed between the germanium absorption region 125 and the oxide 110. For example, for processing reasons, it may be difficult or impossible to form the germanium absorption region 125 directly on the oxide 110. Instead, the germanium can be epitaxially grown on a portion of the silicon layer 205, thus leaving a thin sub-layer of the silicon layer 205 beneath the germanium absorption region 125 as shown.

The portion of the silicon layer 205 below the germanium absorption region 125 includes some of the cathode region 115, an N-type region 210, and some of a P-type region 215. The N-type region 210 (which can be heavily doped N-type) blocks any leakage current from bypassing the germanium absorption region 125 and flowing in the silicon layer 205 between the cathode region 115 and the cathode region 135. That is, N-type region 210 is part of a reversed biased PN junction that prevents leakage current. Thus, the germanium absorption region 125 can be formed on the silicon layer 205 without leakage current being able to bypass the germanium absorption region 125.

Although the PD 200 has the heavily doped N-type region 210, the PD 200 functions in a similar way as the PD 100. That is, the interface between the germanium in the germanium absorption region 125 and the P-type region 215 provide a gain region of the PD 200. Further, this gain can occur with low bias voltages being applied between the anode electrode 140 and the cathode electrode 120 (e.g., 1 to 6 V bias voltage between the electrodes 120 and 140). The tradeoff is that the PD 200 may have a relatively slow speed (e.g., less than 10 MHz) compared to typical APDs.

While FIG. 2 illustrates one anode and one cathode, in other embodiments, the PD 200 may have multiple anode regions or multiple cathode regions. Further, while FIG. 1 illustrates that the germanium absorption region 125 is undoped, in another embodiment the top of this region 125 can be doped P+ so it can function as the cathode region 115. In that case, the cathode electrode 120 can contact the top of the germanium absorption region 125 and the cathode region 115 to the right of the germanium absorption region 125 can be omitted. Thus, whether the cathode region is formed in the silicon (e.g., the cathode region 115) or is disposed on top of the germanium absorption region 125, both the anode and the cathode regions are P-type.

In general, the PD 100 in FIG. 1 and the PD 200 in FIG. 2 can be referred to as a P+PP+ structure, where the cathode and anode regions are the two P+ regions and the lighter doped P region (e.g., the region 130 in FIG. 1 and the region 215 in FIG. 2) is the P region of the structure.

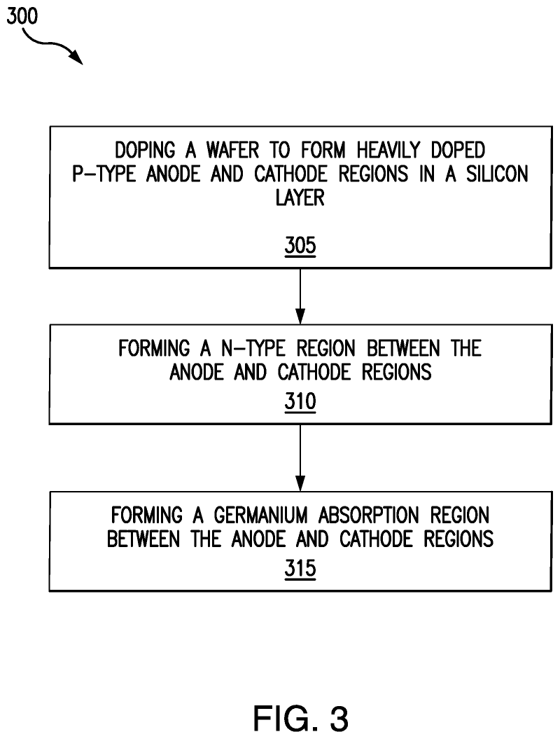

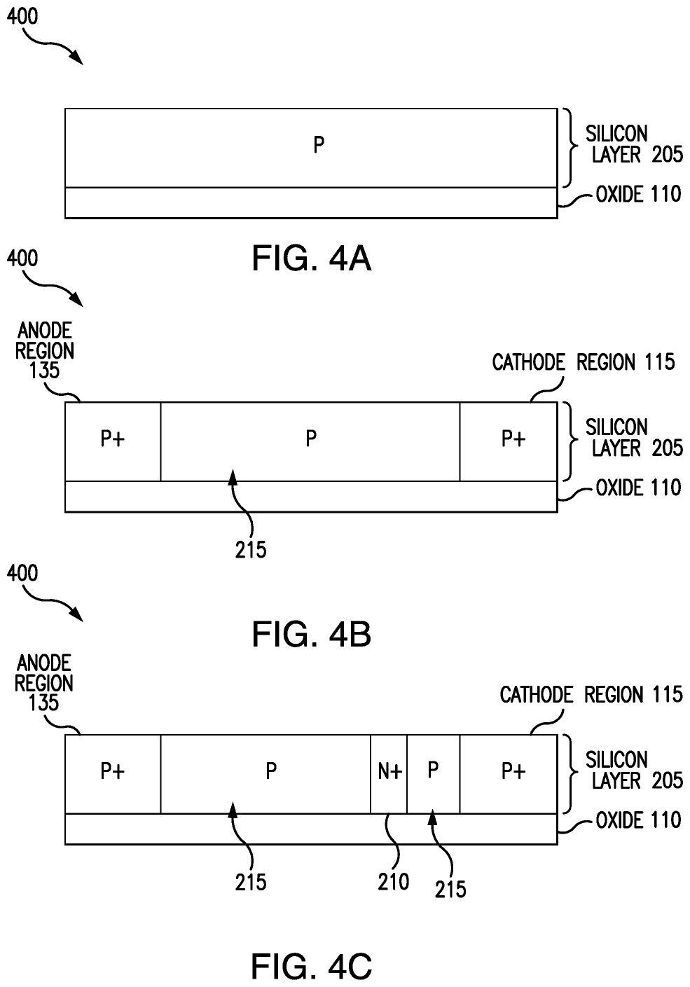

FIG. 3 is a flowchart of a method 300 for forming a photodetector, according to one embodiment. For ease of explanation, the blocks of the method 300 are discussed in tandem with FIGS. 4A-4E which illustrate steps for forming a photodetector.

For example, FIG. 4A illustrates a wafer 400 that includes the silicon layer 205 formed on the oxide 110. The wafer 400 may be a SOI structure where the oxide 110 is a BOX. Thus, there may be a crystalline silicon substrate below the oxide 110 in the wafer 400, which is not shown.

Further, FIG. 4A illustrates that the wafer 400 has already been doped P-type such that the entire silicon layer 205 is a P doped region. This doping may have been introduced when the wafer 400 was grown from a crystal ingot. The ingot can then be sawed and processed to form the P-type silicon layer 205 on the oxide 110. Alternatively, ion implantation can be used to make the silicon layer 205 P-type.

At block 305, the wafer is doped to form a heavily doped P-type anode and cathode regions in a silicon layer. FIG. 4B illustrates forming the anode region 135 and the cathode region 115 on opposite sides of the P-type region 215. As mentioned above, the P-type region 215 may be doped lighter P-type than the cathode region 115 and anode region 135.

At block 310, a N-type region is formed between the anode and cathode regions. FIG. 4C illustrates forming the N-type region 210 in the P-type region 215, such that the N-type region 210 separates the P-type region 215 shown in FIG. 4B into two sub-portions. That is, a first sub-portion of the P-type region 215 contacts the cathode region 115 while the second sub-portion of the P-type region 215 contacts the anode region 135.

In one embodiment, ion implantation is used to form the N-type region 210.

At block 315, the germanium absorption region is formed between the anode and cathode regions. FIG. 4D illustrates etching a trench 405 in the silicon layer 205. Specifically, the trench 405 is etched in portions of the regions 210, 215, and 115. However, the trench 405 could be alternatively etched only in the regions 210 and 215, but not in the cathode region 115. In general, the trench 405 is formed above the N-type region 210 so that the region 210 can block any leakage current between the cathode region 115 and the anode region 135. For example, if the N-type region 210 is sufficiently wide, then the trench 405 may be etched only in the N-type region 210. Stated differently, the trench 405 is formed in the silicon layer 205 so that the N-type region 210 is between the trench 405 and the oxide 110.

As shown, the etching process is controlled so that the trench 405 does not extend all the way to the oxide 110, instead leaving a thin sub-layer of the silicon layer 205. In one embodiment, the thickness of the sub-layer is 10-100 nm.

FIG. 4E illustrates forming germanium in the trench 405 in FIG. 4D to create the germanium absorption region. The germanium can be epitaxially grown or deposited onto the silicon at the bottom of the trench 405. FIG. 4E illustrates that the germanium in the germanium absorption region 125 extends above a top surface of the silicon layer 105, but this is not a requirement. In other embodiments, the germanium may be deposited such that it is level with the top surface of the silicon layer 105, or is partially recessed relative to the top surface of the silicon layer 105.

The thickness of the germanium absorption region 125 can range from 100-500 nm. The width of the germanium absorption region 125 can range from 500-1000 nm.

Further, the method 300 can also be used to form a PD 100 shown in FIG. 1. In that case, the germanium absorption region 125 is formed directly on the oxide 110 which means the N-type region 210 can be omitted.

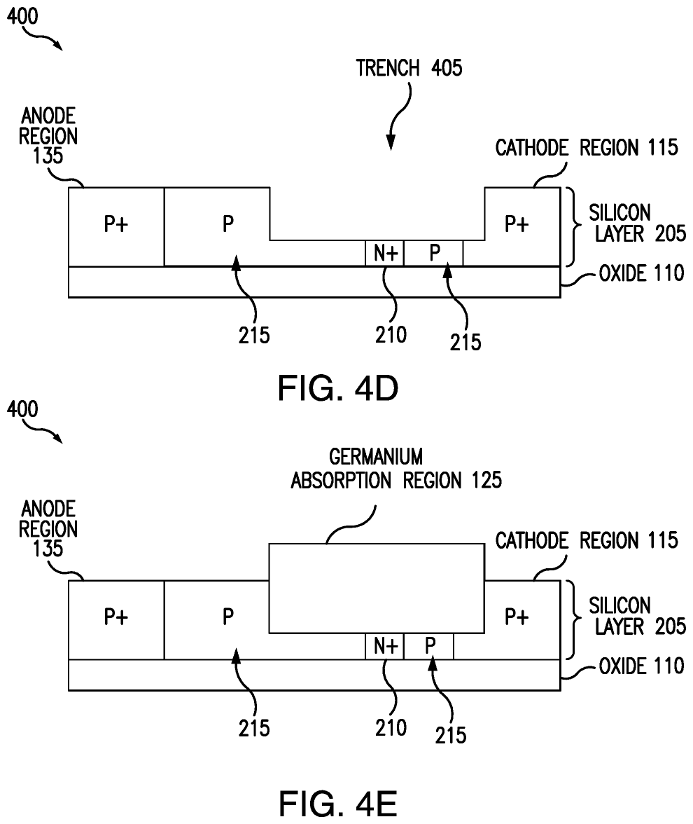

FIG. 5 is a chart 500 for a photodetector that can generate gain at low voltages and low speeds, according to one embodiment. FIG. 5 shows experimental data from a device implementing the Ge/Si heterojunction architecture shown in FIGS. 1 and 2 such as between the germanium absorption region and the lighter doped P-type region 130 (in FIG. 1) or the P-type region 215 (in FIG. 2). More specifically, the chart 500 illustrates photocurrent gain above nominal responsivity as a function of the applied voltage.

As shown, a gain is achieved in the presence of small bias voltages, unlike in a typical APD which has a high threshold voltage (e.g., a breakdown voltage) before appreciable gain occurs. Moreover, the gain for the PDs described above increases in an approximately linear manner as the voltage increases.

FIG. 6 illustrates conduction and valence bands for a germanium silicon interface, according to one embodiment. The left side of FIG. 6 illustrates the conduction and valence bands 640, 645 for germanium while the right side of FIG. 6 illustrates the conduction and valence bands 640, 645 of P-doped silicon. A barrier 650 illustrates the discontinuity in the valence and conduction bands 640, 645 present at the Si/Ge heterointerface. This barrier 650 makes it difficult for negative photo carriers to move from the germanium to the silicon as well as positive photo carriers to move from the silicon into the germanium.

The arrow 605 illustrates light striking the germanium (e.g., the germanium absorption region 125 in FIGS. 1 and 2) and creating positive and negative photo carriers. The arrow 610 illustrates the positive photo carriers (i.e., primary hole photocurrent) moving to the anode (e.g., the anode region 135 in FIGS. 1 and 2). The arrow 615 illustrates the negative photo carriers moving to the silicon (e.g., the cathode region 115 in FIG. 1 or 2). These negative photo carriers accumulate at the barrier 650.

As shown by the arrow 620, the negative accumulated (or trapped) charge modulates the valence band barrier height, resulting in a secondary photocurrent of injected holes moving from the silicon region into the germanium. That is, reducing the valence band discontinuity at the barrier 650 means the positive carriers (e.g., holes) in the silicon are more likely to move into the germanium as shown by arrow 625. This secondary photocurrent can be substantially larger than the primary photocurrent shown by the arrow 610, thus resulting in gain. Stated differently, the number of holes that can move from the silicon to the germanium due to reducing the valence band discontinuity is much larger than the number of electrons needed to lower the barrier 650, which results in gain. When light no longer strikes the germanium, the accumulated electrons at the barrier 650 disappear, thereby increasing the discontinuity and preventing the holes in the silicon from moving into the germanium. As such, the structure has low dark current.

The gain from adjusting the valence band barrier height can also be adjusted by changing the bias voltage. This is shown in chart 500 in FIG. 5. In this manner, a low-voltage PD with gain can be generated using the P+PP+ structure described above.

In the current disclosure, reference is made to various embodiments. However, the scope of the present disclosure is not limited to specific described embodiments. Instead, any combination of the described features and elements, whether related to different embodiments or not, is contemplated to implement and practice contemplated embodiments. Additionally, when elements of the embodiments are described in the form of “at least one of A and B,” or “at least one of A or B,” it will be understood that embodiments including element A exclusively, including element B exclusively, and including element A and B are each contemplated. Furthermore, although some embodiments disclosed herein may achieve advantages over other possible solutions or over the prior art, whether or not a particular advantage is achieved by a given embodiment is not limiting of the scope of the present disclosure. Thus, the aspects, features, embodiments and advantages disclosed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

In view of the foregoing, the scope of the present disclosure is determined by the claims that follow.

We claim:

1. A photodetector, comprising:
a germanium absorption region; and
a silicon layer comprising a P-type anode region and a P-type cathode region, wherein the germanium absorption region is disposed between the P-type anode region and the P-type cathode region.

2. The photodetector of claim 1, wherein the silicon layer comprises a P-type region between the germanium absorption region and the P-type cathode region, wherein the P-type cathode region is more heavily doped P-type than the P-type region.

3. The photodetector of claim 2, wherein the germanium absorption region is at least partially recessed in the silicon layer, wherein the P-type region directly contacts a first side of the germanium absorption region, and the P-type anode region directly contacts a second side of the germanium absorption region which is opposite the first side, wherein the P-type anode region is more heavily doped P-type than the P-type region.

4. The photodetector of claim 1, wherein the silicon layer comprises an N-type region disposed underneath the germanium absorption region to block current from flowing from the P-type anode region to the P-type cathode region.

5. The photodetector of claim 4, wherein the N-type region is disposed between the germanium absorption region and an oxide layer on which the silicon layer is disposed.

6. The photodetector of claim 5, wherein the oxide layer is a buried oxide.

7. The photodetector of claim 1, wherein the photodetector is configured to generate gain when a bias voltage is applied at the P-type cathode region and the P-type anode region.

8. A method, comprising:
doping a wafer to form a P-type anode region and a P-type cathode region in a silicon layer; and
forming a germanium absorption region between the P-type anode region and the P-type cathode region.

9. The method of claim 8, further comprising:
providing a P-type region between the P-type cathode region and the germanium absorption region, wherein the P-type cathode region is more heavily doped P-type than the P-type region.

10. The method of claim 8, further comprising:
etching a trench in the silicon layer; and
forming the germanium absorption region in the trench.

11. The method of claim 10, wherein the P-type region directly contacts a first side of the germanium absorption region, and the P-type anode region directly contacts a second side of the germanium absorption region which is opposite the first side, wherein the P-type anode region is more heavily doped P-type than the P-type region.

12. The method of claim 10, further comprising, before etching the trench:
forming an N-type region in the silicon layer, wherein etching the trench removes a portion of the N-type region.

13. The method of claim 12, the N-type region blocks current from flowing from the P-type anode region to the P-type cathode region.

14. The method of claim 13, wherein the N-type region is disposed between the germanium absorption region and an oxide layer on which the silicon layer is disposed.

15. A photodetector, comprising:
a germanium absorption region;
a silicon layer;
a P-type anode region; and
a P-type cathode region, wherein one of the P-type anode region and P-type cathode region is formed in the silicon layer and the other one of the P-type anode region and the P-type cathode region is at a top of the germanium absorption region.

16. The photodetector of claim 15, wherein the P-type cathode region is formed in the silicon layer and the P-type anode region is at the top of the germanium absorption region, wherein the silicon layer comprises a P-type region between the germanium absorption region and the P-type cathode region, wherein the P-type cathode region is more heavily doped P-type than the P-type region.

17. The photodetector of claim 16, wherein the germanium absorption region is at least partially recessed in the silicon layer, wherein the P-type region directly contacts a first side of the germanium absorption region.

18. The photodetector of claim 15, wherein the silicon layer comprises an N-type region disposed underneath the germanium absorption region.

19. The photodetector of claim 18, wherein the N-type region is disposed between the germanium absorption region and an oxide layer on which the silicon layer is disposed.

20. The photodetector of claim 15, wherein the photodetector is configured to generate gain when a bias voltage is applied at the P-type cathode region and the P-type anode region.
